(19) United States
(12) Patent Application Publication
(10) Pub. No.: US 2015/0035101 A1
(43) Pub. Date: Feb. 5, 2015

(54) SOLID-STATE IMAGING DEVICE AND METHOD FOR MANUFACTURING THE SOLID-STATE IMAGING DEVICE

(71) Applicant: Kabushiki Kaisha Toshiba, Minato-ku (JP)

(72) Inventors: Junji Naruse, Oita-shi (JP); Nagataka Tanaka, Oita-shi (JP)

(73) Assignee: Kabushiki Kaisha Toshiba, Minato-ku (JP)

(21) Appl. No.: 14/174,360

(22) Filed: Feb. 6, 2014

(30) Foreign Application Priority Data
Aug. 5, 2013 (JP) 2013-162584

(51) Int. Cl. H01L 27/146

(52) U.S. Cl. CPC H01L 27/14625; H01L 27/14685
USPC 257/432; 438/72

(57) ABSTRACT

According to one embodiment, a solid-state imaging device is provided. The solid-state imaging device includes a photoelectric conversion element, a first anti-reflection film, an intermediate film, and a second anti-reflection film. The photoelectric conversion element is disposed corresponding to each of a plurality of colored lights. The first anti-reflection film is disposed on a photo-receiving surface side of the photoelectric conversion element. The intermediate film is disposed on a photo-receiving surface side of the first anti-reflection film. The second anti-reflection film is disposed on a photo-receiving surface side of the intermediate film. At least one of the first anti-reflection film, the intermediate film, and the second anti-reflection film has different film thicknesses for respective colored lights to be received.

### CROSS-REFERENCE TO RELATED APPLICATIONS

This application is based upon and claims the benefit of priority from Japanese Patent Application No. 2013-162584, filed on Aug. 5, 2013; the entire contents of which are incorporated herein by reference.

### FIELD

Embodiments described herein relate generally to a solid-state imaging device and a method for manufacturing the solid-state imaging device.

### BACKGROUND

Conventionally, a solid-state imaging device includes a plurality of photoelectric conversion elements disposed corresponding to respective pixels of a captured image. Each photoelectric conversion element photoelectrically converts incident light into electric charge of an amount corresponding to the received light intensity and accumulates the electric charges in a charge storage region. The solid-state imaging device takes an image by reading out electric charges from the charge storage region for each photoelectric conversion element.

For this solid-state imaging device, downscaling of each photoelectric conversion element has been being developed. Along with this development, a light-receiving area for each photoelectric conversion element is prone to be reduced. Accordingly, it is preferred to improve the light-receiving efficiency of the photoelectric conversion element so as to receive a greater amount of light at this limited light-receiving area.

### BRIEF DESCRIPTION OF THE DRAWINGS

FIG. 1 is a block diagram illustrating a schematic configuration of a digital camera that includes a solid-state imaging device according to a first embodiment;

FIG. 2 is a block diagram illustrating a schematic configuration of the solid-state imaging device according to the first embodiment;

FIG. 3 is a schematic plan view illustrating a configuration of a pixel array according to the first embodiment;

FIG. 4 is a schematic cross-sectional view of the pixel array according to the first embodiment;

FIG. 5 is a graph of an experimental result illustrating a relationship between: a wavelength of a colored light to be received at a photoelectric conversion element according to the first embodiment, and transmittance of the colored light at the silicon interface;

FIG. 6A to 6D are schematic cross-sectional views illustrating a manufacturing process of the solid-state imaging device according to the first embodiment;

FIG. 7 is a schematic cross-sectional view of a pixel array according to a second embodiment; and

FIG. 8 is a schematic cross-sectional view of a pixel array according to a third embodiment.

### DETAILED DESCRIPTION

In general, according to one embodiment, a solid-state imaging device is provided. The solid-state imaging device includes a photoelectric conversion element, a first anti-reflection film, an intermediate film, and a second anti-reflection film. The photoelectric conversion element is disposed corresponding to each of a plurality of colored lights. The first anti-reflection film is disposed on a photo-receiving surface side of the photoelectric conversion element. The intermediate film is disposed on a photo-receiving surface side of the first anti-reflection film. The second anti-reflection film is disposed on a photo-receiving surface side of the intermediate film. At least one of the first anti-reflection film, the intermediate film, and the second anti-reflection film has different film thicknesses for each colored light to be received.

Exemplary embodiments of a solid-state imaging device and a method for manufacturing the solid-state imaging device will be explained below in detail with reference to the accompanying drawings. The present invention is not limited to the following embodiments.

### First Embodiment

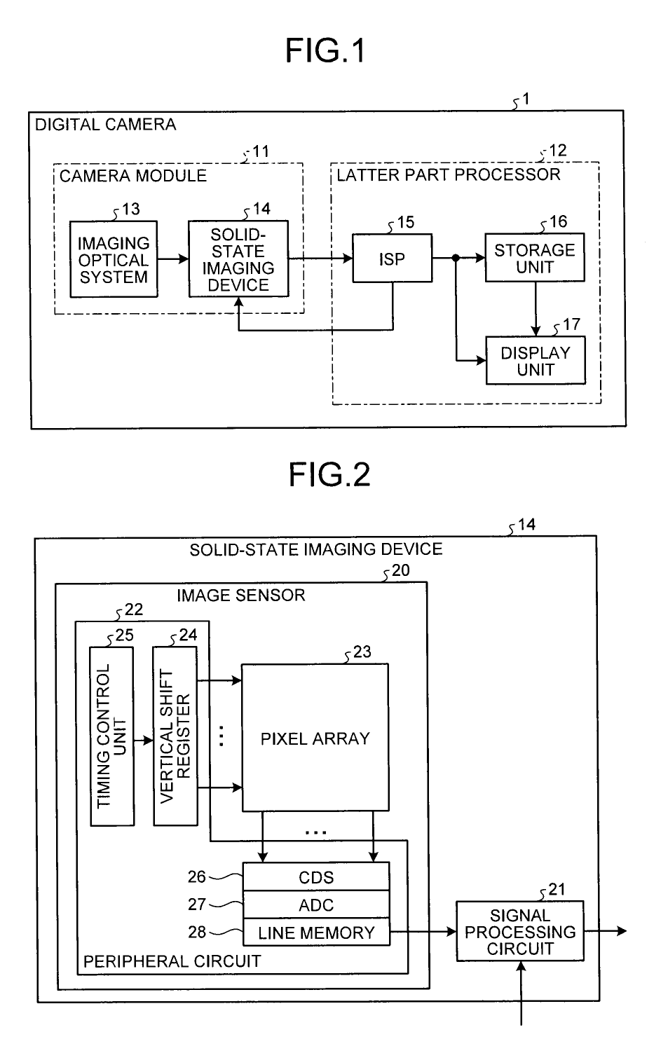

FIG. 1 is a block diagram illustrating a schematic configuration of a digital camera 1 with a solid-state imaging device 14 according to a first embodiment. As illustrated in FIG. 1, the digital camera 1 includes a camera module 11 and a latter part processor 12.

The camera module 11 includes an imaging optical system 13 and the solid-state imaging device 14. The imaging optical system 13 receives light from a photogenic subject and forms an image of a photographic subject image. The solid-state imaging device 14 takes the photogenic subject image formed by the imaging optical system 13, and outputs an image signal obtained by taking the image to the latter part processor 12. This camera module 11 is applied, for example, to electronic devices such as a portable terminal with camera, in addition to the digital camera 1.

The latter part processor 12 includes an Image Signal Processor (ISP) 15, a storage unit 16, and a display unit 17. The ISP 15 performs a signal process of the image signal input from the solid-state imaging device 14. This ISP 15, for example, performs a high quality image process such as a denoising process, a defective pixel correction process, and a resolution conversion process.

Then, the ISP 15 outputs the image signal after the signal process to the storage unit 16, the display unit 17, and a signal processing circuit 21, which will be described below (see FIG. 2). The signal processing circuit 21 is included in the solid-state imaging device 14 in the camera module 11. The image signal fed back from the ISP 15 to the camera module 11 is used for adjustment and control of the solid-state imaging device 14.

The storage unit 16 stores the image signal input from the ISP 15 as an image. The storage unit 16 outputs the image signal of the stored image to the display unit 17 according to, for example, an operation by the user. The display unit 17 displays an image corresponding to the image signal input from the ISP 15 or the storage unit 16. This display unit 17 is, for example, a liquid crystal display.

Next, with reference to FIG. 2, the solid-state imaging device 14 included in the camera module 11 will be described. FIG. 2 is a block diagram illustrating a schematic configuration of the solid-state imaging device 14 according to the first embodiment. As illustrated in FIG. 2, the solid-state imaging device 14 includes an image sensor 20 and the signal processing circuit 21.

The image sensor 20 includes a peripheral circuit 22 and a pixel array 23. The peripheral circuit 22 includes a vertical shift register 24, a timing control unit 25, a correlated double sampling unit (CDS) 26, an analog-to-digital converter (ADC) 27, and a line memory 28.

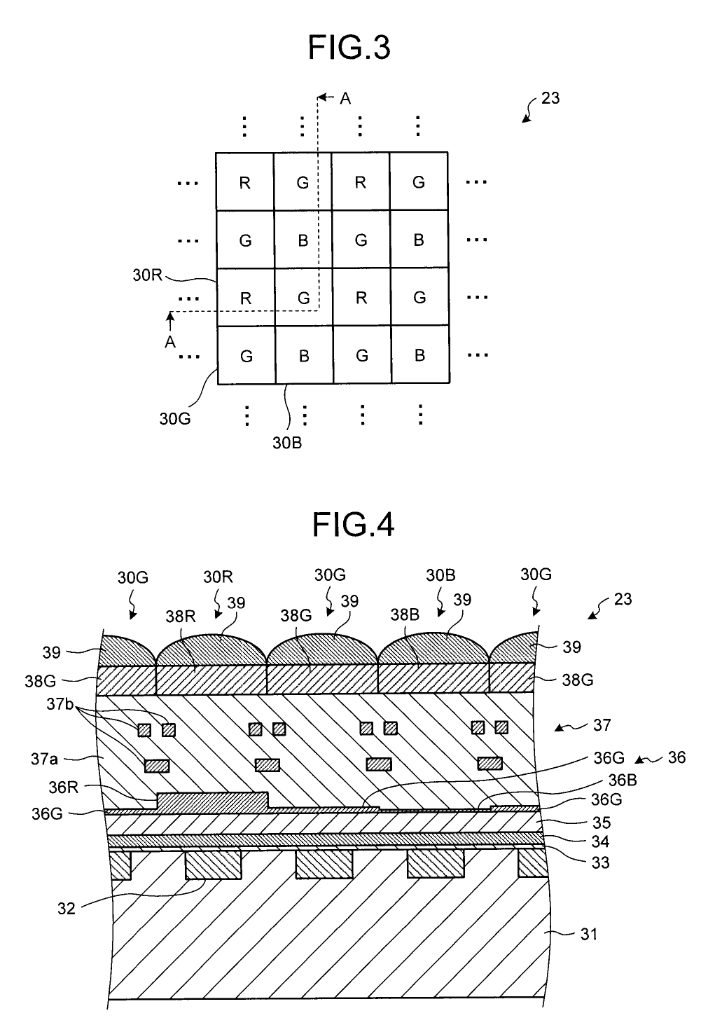

The pixel array 23 is disposed in an imaging area of the image sensor 20. A configuration of this pixel array 23 will be described with reference to FIG. 3. FIG. 3 is a schematic plan view illustrating the configuration of this pixel array 23 according to the first embodiment.

As illustrated in FIG. 3, the pixel array 23 includes a plurality of pixel cells 30R, 30G, and 30B disposed in an array (matrix) pattern. The pixel cells 30R, 30G, and 30B detect respective assigned signal levels of red light, green light, and blue light.

The pixel cell 30R includes a color filter that transmits red light. The pixel cell 30G includes a color filter that transmits green light. The pixel cell 30B includes a color filter that transmits blue light. The pixel cells 30R, 30G, and 30B each include a photoelectric conversion element that generates a signal charge corresponding to the amount of received light when a colored light after transmission through the color filter is received. The specific configurations of these pixel cells 30R, 30G, and 30B will be described later.

Here, in FIG. 3, the case where the pixel cells 30R, 30G, and 30B are arranged in a Bayer array has been illustrated. The arrangement of the pixel cells 30R, 30G, and 30B is not limited to the Bayer array.

The timing control unit 25 illustrated in FIG. 2 is a processor that outputs a pulse signal to the vertical shift register 24. The pulse signal becomes a reference of operation timing. The vertical shift register 24 is a processor that outputs a selection signal to the pixel array 23. The selection signal is a signal for sequentially selecting a photoelectric conversion element to read out the signal charge among the plurality of photoelectric conversion elements, which are arranged in an array (matrix) pattern, in units of lines.

In the pixel array 23, the signal charge accumulated in each photoelectric conversion element to be selected with a selection signal input from the vertical shift register 24 in units of lines is output from the photoelectric conversion element to the CDS 26 as a pixel signal indicating luminance of a corresponding pixel.

The CDS 26 is a processor that removes noise from the pixel signal input from the pixel array 23 by correlated double sampling and then outputs the pixel signal to the ADC 27. The ADC 27 is a processor that converts an analog pixel signal input from the CDS 26 into a digital pixel signal and then outputs the digital pixel signal to the line memory 28. The line memory 28 is a processor that temporarily holds the pixel signals input from the ADC 27 and then outputs the pixel signals to the signal processing circuit 21 for each line of the photoelectric conversion elements in the pixel array 23.

The signal processing circuit 21 is a processor that performs a predetermined signal process to the pixel signal input from the line memory 28 and then outputs the pixel signal to the latter part processor 12. The signal processing circuit 21 performs a signal process, for example, lens shading correction, defect correction, and noise reduction process on the pixel signal.

Thus, in the image sensor 20, the plurality of photoelectric conversion elements arranged at the pixel array 23 photoelectrically converts incident light into signal charges in an amount corresponding to the amount of the received light and then accumulates the signal charges. Then, the peripheral circuit 22 reads out the signal charge accumulated in each photoelectric conversion element as a pixel signal, so as to take an image.

Here, one of possible methods for improving light-receiving efficiency of the photoelectric conversion element is disposing an anti-reflection film at the photo-receiving surface side of the photoelectric conversion element. The anti-reflection film is a film that reduces reflected light using the interference effect of light.

In the solid-state imaging device 14 according to the first embodiment, the anti-reflection film structure is optimized for each of the pixel cells 30R, 30G, and 30B (see FIG. 3), so as to further improve the light-receiving efficiency of the photoelectric conversion element. A configuration of this anti-reflection film will be described with reference to FIG. 4.

FIG. 4 is a schematic cross-sectional view illustrating the pixel array 23 according to the first embodiment. FIG. 4 illustrates a schematic cross-sectional view taken along the arrow A-A illustrated in FIG. 3.

As illustrated in FIG. 4, the pixel array 23 includes a photoelectric conversion element 32, an insulating film 33, a first anti-reflection film 34, an intermediate film 35, a second anti-reflection film 36, and a multilayer interconnection layer 37, which are sequentially laminated on a semiconductor substrate 31.

The pixel array 23 includes color filters 38R, 38G, and 38B in positions facing the respective photoelectric conversion elements 32 on the top surface of the multilayer interconnection layer 37, and includes microlenses 39 on the respective top surfaces of the color filters 38R, 38G, and 38B.

The semiconductor substrate 31 is a substrate such as a single-crystal silicon substrate. The photoelectric conversion element 32 is constituted by, for example, a part of the impurity diffused region formed on the top surface of the semiconductor substrate 31. The photoelectric conversion element 32 photoelectrically converts colored lights entering through the microlenses 39 and the color filters 38R, 38G, and 38B into signal charges (electrons) corresponding to the amount of received light, and accumulates the signal charges. Here, one photoelectric conversion element 32 is assumed to correspond to one pixel.

The insulating film 33 is disposed on the top surface of the semiconductor substrate 31 where the photoelectric conversion element 32 is formed. The insulating film 33 is formed of, for example, a silicon oxide film. The insulating film 33 has a film thickness of, for example, 5 nm to 15 nm.

The first anti-reflection film 34 is disposed on the top surface of the insulating film 33. The first anti-reflection film 34 is formed of, for example, a silicon nitride film.

This first anti-reflection film 34 reduces reflected light that is reflected at the interface between the semiconductor substrate 31 and the insulating film 33 or the interface between the photoelectric conversion element 32 and the insulating film 33 (hereinafter described as “the silicon interface”) using the interference effect of light. Here, the film thickness of the first anti-reflection film 34 is, for example, 40 nm to 50 nm.

The intermediate film 35 is disposed on the top surface of the first anti-reflection film 34. The intermediate film 35 is formed of, for example, an insulating film such as a silicon oxide film. The intermediate film 35 has a film thickness of, for example, 100 nm to 120 nm.

The second anti-reflection film 36 is disposed on the top surface of the intermediate film 35. The second anti-reflection film 36 is formed of, for example, a silicon nitride film. Similarly to the first anti-reflection film 34, the second anti-reflection film 36 reduces reflected light from the silicon interface using the interference effect of light.

Here, while the illustration is omitted, through-holes for, for example, allowing passage of via contacts are partially formed in the first anti-reflection film 34 and the second anti-reflection film 36.

The multilayer interconnection layer 37 is disposed on the top surface of the second anti-reflection film 36. The multilayer interconnection layer 37 includes an interlayer insulating film 37a and multilayer interconnections 37b. The interlayer insulating film 37a is formed of silicon oxide. The multilayer interconnections 37b are disposed inside of the interlayer insulating film 37a, and is used for reading out of the photoelectrically converted signal charge and for transmission of a drive signal or similar signal to each circuit element at the peripheral circuit 22 (see FIG. 2).

The color filters 38R, 38G, and 38B are disposed corresponding to the photoelectric conversion elements 32 on the top surface of the multilayer interconnection layer 37. The color filter 38R is a filter that selectively transmits red light. The color filter 38G is a filter that selectively transmits green light. The color filter 38B is a filter that selectively transmits blue light.

The microlens 39 is a plano-convex lens disposed on each of the top surfaces of the color filters 38R, 38G, and 38B. The microlens 39 condenses incident light that enters into the pixel array 23 onto the photoelectric conversion element 32.

In this pixel array 23 according to the first embodiment, the second anti-reflection film 36 has the film thickness varied in each of the pixel cells 30R, 30G, and 30B.

That is, in the second anti-reflection film 36, a region 36R corresponding to the pixel cell 30R is formed thicker than a region 36G corresponding to the pixel cell 30G. Additionally, the region 36G corresponding to the pixel cell 30G is formed thicker than a region 36B corresponding to the pixel cell 30B.

Here, the film thickness of the region 36R corresponding to the pixel cell 30R is 75 nm to 85 nm. The film thickness of the region 36G corresponding to the pixel cell 30G is 15 nm to 25 nm. The film thickness of the region 36B corresponding to the pixel cell 30B is 5 nm to 15 nm.

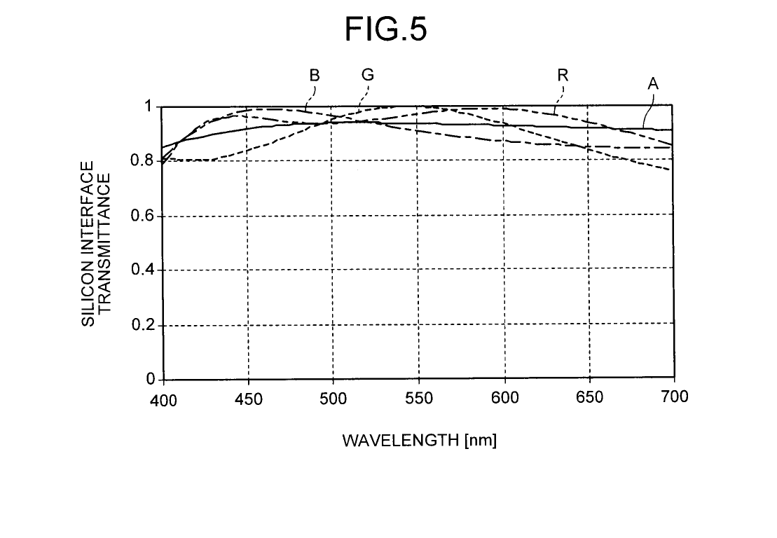

Thus, in the pixel array 23 according to the first embodiment, the film thickness of the second anti-reflection film 36 is varied for each colored light to be received so as to obtain high light-receiving efficiency for any of red light, green light, and blue light. This point will be described with reference to FIG. 5.

FIG. 5 is a graph of an experimental result illustrating a relationship between: a wavelength of a colored light to be received at the photoelectric conversion element 32 according to the first embodiment, and transmittance of the colored light at the silicon interface. In FIG. 5, the wavelength of the colored light is indicated on the horizontal axis while the transmittance of the colored light at the silicon interface is indicated on the vertical axis.

In FIG. 5, a characteristic of the anti-reflection film structure corresponding to the pixel cell 30R is illustrated by a two-dot chain line. A characteristic of the anti-reflection film structure corresponding to the pixel cell 30G is illustrated by a dashed line. A characteristic of the anti-reflection film structure corresponding to the pixel cell 30B is illustrated by a one-dot chain line. Here, the anti-reflection film structure for each of the pixel cells 30R, 30G, and 30B means the film structure that includes the first anti-reflection film 34, the intermediate film 35, and the second anti-reflection film 36, which are illustrated in FIG. 4.

In FIG. 5, a characteristic of the conventional anti-reflection film structure is illustrated by a solid line. Here, the conventional anti-reflection film structure is a structure where a silicon oxide film is disposed on a silicon substrate and a silicon nitride film with a constant film thickness is disposed on this silicon oxide film. In the anti-reflection film structure illustrated here, the film thickness is optimized to accord with green colored light.

As illustrated in FIG. 5, a silicon-interface transmittance (hereinafter described simply as “transmittance”) in the conventional anti-reflection film structure is highest approximately at 530 nm within the wavelength range of green colored light. The transmittance approximately at 610 nm within the wavelength range of red colored light and the transmittance approximately at 450 nm within the wavelength range of blue colored light (see “A” in FIG. 5) are lower than that at 530 nm.

Thus, in the conventional anti-reflection film structure, the film thickness of the anti-reflection film is optimized such that a peak in the transmittance with respect to one of the colored lights appears. Therefore, it has been difficult to sufficiently improve the transmittance for the other colored lights.

In contrast, in the anti-reflection film structure according to the first embodiment, each of the transmittances of the pixel cells 30R, 30G, and 30B is maximum in a wavelength range of a corresponding colored light. That is, the transmittance in the pixel cell 30R corresponding to red light is maximum approximately at 610 nm within the wavelength range of red colored light. The transmittance in the pixel cell 30G corresponding to green light is maximum approximately at 530 nm within the wavelength range of green colored light (see “R” and “G” in FIG. 5). The transmittance in the pixel cell 30B corresponding to blue light is maximum approximately at 450 nm within the wavelength range of blue colored light (see “B” in FIG. 5).

Thus, in the anti-reflection film structure according to the first embodiment, the film thickness of the second anti-reflection film 36 is varied in each of the pixel cells 30R, 30G, and 30B such that the peak position of the transmittance is optimized in each of pixel cells 30R, 30G, and 30B. Accordingly, high transmittance can be obtained for any of red light, green light, and blue light.

The maximum value of the transmittance in the conventional anti-reflection film structure is about 0.95. In contrast, in the anti-reflection film structure according to the first embodiment, the maximum values of the transmittance within the respective wavelength ranges of the colored lights (610 nm, 530 nm, and 450 nm) all indicate values close to 100%.

Thus, in the anti-reflection film structure according to the first embodiment, the transmittance within the wavelength range of each colored light is found to be improved more than that of the conventional anti-reflection film structure.

As one of the reasons for this improvement, the anti-reflection film structure according to the first embodiment has a three-layered structure that includes the first anti-reflection film 34, the intermediate film 35, and the second anti-reflection film 36. That is, a reflected light that is not sufficiently reduced is reflected again at the interface between the intermediate film 35 and the second anti-reflection film 36. This is likely to improve the transmittance more than that of the anti-reflection film structure in a single layer structure.

Accordingly, the anti-reflection film structure according to the first embodiment uniformly transmits the respective colored light with higher transmittance than the conventional anti-reflection film structure. Therefore, the anti-reflection film structure according to the first embodiment can improve the light-receiving efficiency of the photoelectric conversion element 32.

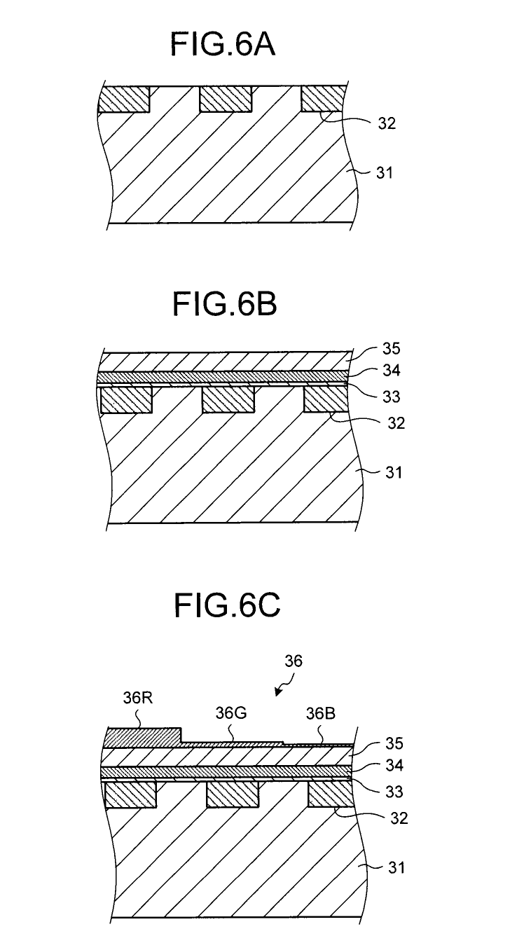

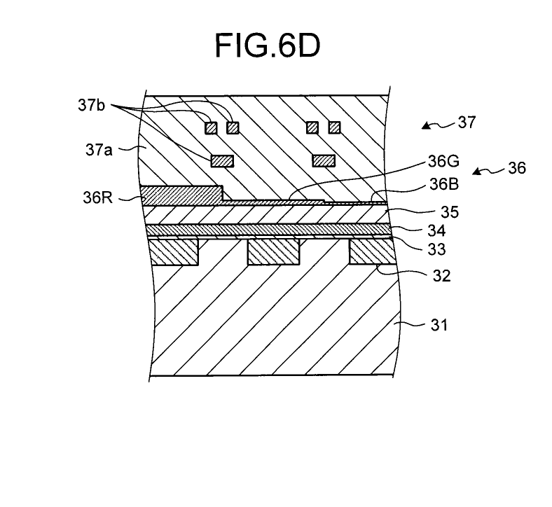

Next, a description will be given of a method for manufacturing the solid-state imaging device 14 according to the first embodiment with reference to FIG. 6A to FIG. 6D. FIG. 6A to FIG. 6D are schematic cross-sectional views illustrating a manufacturing process of the solid-state imaging device 14 according to the first embodiment. A method for manufacturing a portion other than the pixel array 23 in the solid-state imaging device 14 is similar to that of a typical CMOS image sensor. Therefore, a description will be given of a method for manufacturing the pixel array 23 portion in the solid-state imaging device 14 below.

As illustrated in FIG. 6A, in the case where the pixel array 23 is manufactured, the semiconductor substrate 31 such as a silicon substrate is prepared. The photoelectric conversion element 32 is formed on the top surface (the photo-receiving surface) side of this semiconductor substrate 31.

For example, an N-type silicon region is formed by epitaxial growth on a principal surface of the semiconductor substrate 31. In this N-type silicon region, P-type impurity is implanted by ion implantation on formation positions for the element isolation. Subsequently, an annealing process is performed so as to form a P-type silicon region. Accordingly, a plurality of photoelectric conversion elements 32, which is electrically element-isolated by the P-type silicon region, is formed on the semiconductor substrate 31 in an array pattern in plan view.

The method for forming the photoelectric conversion element 32 is not limited to the above-described example. For example, the P-type silicon region may be formed by forming openings at the formation positions for element isolation in the N-type silicon region, and subsequently by epitaxial growth of a silicon layer where an impurity such as P is doped inside of the openings.

Subsequently, as illustrated in FIG. 6B, on the top surface of the semiconductor substrate 31 where the photoelectric conversion elements 32 are formed, the insulating film 33, the first anti-reflection film 34, and the intermediate film 35 are sequentially formed with constant film thicknesses.

Subsequently, as illustrated in FIG. 6C, the second anti-reflection film 36 is formed on the top surface of the intermediate film 35. For example, a silicon nitride film is uniformly formed with the same film thickness as that of the region 36B on the top surface of the intermediate film 35. Subsequently, silicon nitride is deposited in a state where the portion of the region 36B is covered with a mask or similar matter, so as to form a thicker region than the region 36B. Subsequently, silicon nitride is deposited again in a state where the portions of the region 36B and the region 36G are covered, so as to form the region 36G and the region 36R thicker than the region 36G. Accordingly, the second anti-reflection film 36 with varied film thicknesses for respective colored lights to be received is formed.

The method for forming the second anti-reflection film 36 is not limited to the above-described example. For example, a silicon nitride film is uniformly formed with the same film thickness as that of the region 36R on the top surface of the intermediate film 35. Subsequently, the silicon nitride film is etched in a state where the region 36R is covered with a mask or similar matter. Thus, the region 36G is formed with a film thickness thinner than that of the region 36R. Subsequently, the silicon nitride film is etched again in a state where the region 36R and the region 36G are covered. Thus, the region 36B thinner than the region 36G is formed.

Subsequently, as illustrated in FIG. 6D, the multilayer interconnection layer 37 is formed on the top surface of the second anti-reflection film 36. The multilayer interconnection layer 37 is formed by repeating, for example, a process for forming the interlayer insulating film 37a of a silicon oxide film or similar film, a process for forming a predetermined interconnection pattern on the interlayer insulating film 37a, and a process for implanting Cu or similar material into the interconnection pattern so as to form the multilayer interconnection 37b.

Subsequently, the color filters 38R, 38G, and 38B and the microlens 39 are sequentially formed on the top surface of the multilayer interconnection layer 37. Thus, the solid-state imaging device 14 that includes the pixel array 23 illustrated in FIG. 4 is manufactured.

As described above, the solid-state imaging device 14 according to the first embodiment has the anti-reflection film structure as a multilayer structure that includes the first anti-reflection film 34, the intermediate film 35, and the second anti-reflection film 36 so as to improve silicon interface transmittance, compared with the conventional anti-reflection film structure.

The solid-state imaging device 14 according to the first embodiment has different film thicknesses of the second anti-reflection film 36 for respective colored lights to be received. Specifically, the film thickness of the second anti-reflection film 36 is formed thicker in the region as the region receives the colored light with the longer wavelength. This ensures high transmittance for any of red light, green light, and blue light.

Accordingly, the solid-state imaging device 14 according to the first embodiment can improve the light-receiving efficiency of the photoelectric conversion element 32.

While in the first embodiment the case where the film thickness of the second anti-reflection film 36 is varied for respective colored lights has been described, the film thickness of the first anti-reflection film 34 may be varied for respective colored lights or the film thickness of the intermediate film 35 may be varied for respective colored lights. Also in the case where the film thickness of the first anti-reflection film 34 or the intermediate film 35 is varied, any configuration is possible insofar as a region for receiving red light is formed thicker than a region for receiving green light and the region for receiving green light is formed thicker than a region for receiving blue light, similarly to the case where the film thickness of the second anti-reflection film 36 is varied.

While in the first embodiment only the film thickness of the second anti-reflection film 36 is varied, the film thicknesses of a plurality of films among the first anti-reflection film 34, the intermediate film 35, and the second anti-reflection film 36 may be varied.

In the first embodiment, the case where the pixel array 23 includes three types of pixel cells of the pixel cell 30R corresponding to red light, the pixel cell 30G corresponding to green light, and the pixel cell 30B corresponding to blue light has been described. However, the pixel array 23 may include a pixel cell corresponding to a colored light other than the above-described colored lights.

For example, the pixel array may include a pixel cell corresponding to white light in addition to the pixel cells 30R, 30G, and 30B. In this case, the second anti-reflection film with a film thickness optimized for white light is disposed also in the pixel cell corresponding to white light. This improves the light-receiving efficiency of the photoelectric conversion element for receiving white light. The film thickness of the second anti-reflection film for receiving white light may be designed to be the same as the film thickness of the region 36G corresponding to green light, which is most sensitive to the human eye.

### Second Embodiment

Here, while in the first embodiment described above the case where the second anti-reflection film 36 is disposed in each of the pixel cells 30R, 30G, and 30B has been described, the pixel cell 30B may be provided without the second anti-reflection film 36.

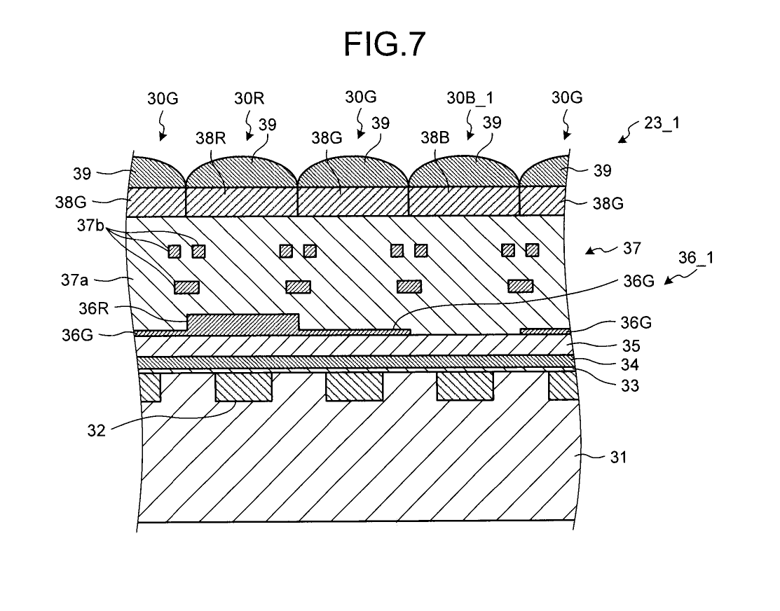

This point will be described with reference to FIG. 7. FIG. 7 is a schematic cross-sectional view of a pixel array according to the second embodiment. In the following description, the same reference numerals are given to the same parts as the already described parts, and the repeated description will be omitted correspondingly.

As illustrated in FIG. 7, a pixel array 23_1 according to the second embodiment includes a pixel cell 30B_1 instead of the pixel cell 30B included in the pixel array 23 according to the first embodiment. In other words, the pixel array 23_1 according to the second embodiment includes a second anti-reflection film 36_1 instead of the second anti-reflection film 36 included in the pixel array 23 according to the first embodiment.

The second anti-reflection film 36_1 according to the second embodiment includes the region 36R corresponding to the pixel cell 30R and the region 36G corresponding to the pixel cell 30G. Therefore, the second anti-reflection film 36_1 is disposed in a region except the region for receiving blue light.

In the case where the pixel array 23_1 that includes this second anti-reflection film 36_1 is manufactured, the photoelectric conversion element 32, the insulating film 33, the first anti-reflection film 34, and the intermediate film 35 are sequentially formed on the top surface of the semiconductor substrate 31 by a similar process to that of the pixel array 23 according to the first embodiment described above.

Subsequently, silicon nitride is deposited on the top surface of the intermediate film 35 until the film thickness becomes the same as that of the region 36G, in a state where the region corresponding to the pixel cell 30B_1 is covered with a mask. Subsequently, silicon nitride is deposited again in a state where the respective regions corresponding to the pixel cell 30B_1 and the pixel cell 30G are covered with a mask. This allows forming the second anti-reflection film 36_1 with the varied film thicknesses in the region 36R and the region 36G in the region other than the region corresponding to the pixel cell 30B_1.

Thus, in the solid-state imaging device according to the second embodiment, the second anti-reflection film 36_1 is disposed in the region other than the region for receiving blue light. This allows reducing the manufacturing processes for the second anti-reflection film 36_1. Accordingly, a low-cost solid-state imaging device can be provided with the photoelectric conversion element 32 having the improved light-receiving efficiency.

Here, the case where the film thickness of the region 36R and the film thickness of the region 36G are different from each other in the second anti-reflection film 36_1 has been described. However, the region 36R and the region 36G may have the uniform film thickness. Accordingly, this allows further reducing manufacturing processes of the second anti-reflection film.

Here, the second anti-reflection film 36_1 is disposed in the region other than the region for receiving blue light. However, the second anti-reflection film may be disposed in a region other than the region for receiving red light. Alternatively, the second anti-reflection film may be disposed in a region other than the region for receiving green light. In both cases, manufacturing processes of the second anti-reflection film can be reduced.

Here, while the case where the pixel array 23_1 includes three types of pixel cells 30R, 30G, and 30B has been described, the pixel array 23_1 may include a pixel cell corresponding to a colored light other than the above-described colored lights.

For example, in the case where the pixel array includes a pixel cell corresponding to white light, any configuration is possible insofar as the second anti-reflection film is disposed in a region except at least one of the region for receiving red light, the region for receiving green light, the region for receiving blue light, and the region for receiving white light.

### Third Embodiment

While in the above-described second embodiment the case where the second anti-reflection film is disposed in the region other than any one region of the region for receiving red light, the region for receiving green light, and the region for receiving blue light has been described, the second anti-reflection film may be disposed in a region other than any two regions of these regions.

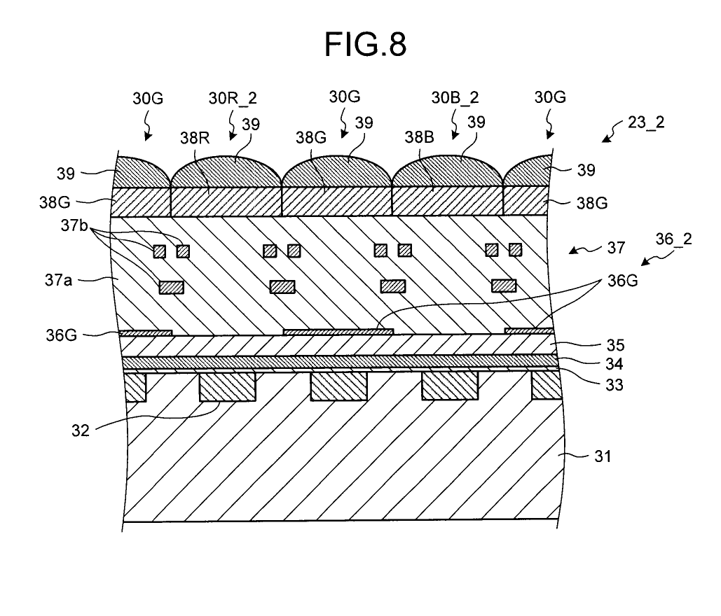

This point will be described with reference to FIG. 8. FIG. 8 is a schematic cross-sectional view of a pixel array according to a third embodiment.

As illustrated in FIG. 8, a pixel array 23_2 according to the second embodiment includes pixel cells 30R_2 and 30B_2 instead of the pixel cells 30R and 30B included in the pixel array 23 according to the first embodiment. In other words, the pixel array 23_2 according to the third embodiment includes a second anti-reflection film 36_2 instead of the second anti-reflection film 36 included in the pixel array 23 according to the first embodiment.

The second anti-reflection film 36_2 according to the third embodiment includes the region 36G corresponding to the pixel cell 30G. Thus, the second anti-reflection film 36_2 is disposed in a region except the region for receiving red light and the region for receiving blue light.

In the case where the pixel array 23_2 that includes this second anti-reflection film 36_2 is manufactured, the photoelectric conversion element 32, the insulating film 33, the first anti-reflection film 34, and the intermediate film 35 are sequentially formed on the top surface of the semiconductor substrate 31 by a similar process to that of the pixel array 23 according to the first embodiment described above.

Subsequently, silicon nitride is deposited on the top surface of the intermediate film 35 until the film thickness becomes the same as that of the region 36G, in a state where the respective regions corresponding to the pixel cell 30R_2 and the pixel cell 30B_2 are covered with a mask. This allows forming the second anti-reflection film 36_2 in the region except the respective regions corresponding to the pixel cell 30R_2 and the pixel cell 30B_2.

Thus, in the solid-state imaging device according to the third embodiment, the second anti-reflection film 36_2 is disposed in the region except the region for receiving red light and the region for receiving blue light, that is, in the region for receiving green light.

Green is a color that is more intense to the human eye than red and blue. Accordingly, disposing the second anti-reflection film 36_2 only in the region for receiving green light allows providing a lower-cost solid-state imaging device while improving the light-receiving efficiency of the photoelectric conversion element 32.

While in third embodiment the second anti-reflection film 36_2 is disposed in the region for receiving green light, the second anti-reflection film may be disposed in the region for receiving red light or the second anti-reflection film may be disposed in the region for receiving blue light depending on the application or similar reason.

While in the third embodiment the case where the pixel array 23_2 includes three types of pixel cells 30R, 30G, and 30B has been described, the pixel array 23_2 may include a pixel cell corresponding to a colored light other than the above-described colored lights.

For example, in the case where the pixel array includes a pixel cell corresponding to white light, the second anti-reflection film may be disposed in a region for receiving white light, in other words, in a region other than the respective regions for receiving red light, green light, and blue light.

While in each embodiment described above the first anti-reflection film and the second anti-reflection film are formed of the same material (silicon nitride), the first anti-reflection film and the second anti-reflection film may be formed of different materials.

While in each embodiment described above the intermediate film is formed of a silicon oxide film, the intermediate film may be formed of a material other than the silicon oxide film.

In each embodiment described above, the case where the image sensor is a front-illuminated Complementary Metal Oxide Semiconductor (CMOS) image sensor where the interconnection layer is formed on the photo-receiving surface side of the photoelectric conversion element has been described. However, the image sensor may be any image sensor, for example, a back-illuminated CMOS image sensor, where the interconnection layer is formed on the opposite surface side of the photo-receiving surface of the photoelectric conversion element, and a Charge Coupled Device (CCD) image sensor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a photoelectric conversion element disposed corresponding to each of a plurality of colored lights;
a first anti-reflection film disposed on a photo-receiving surface side of the photoelectric conversion element;
an intermediate film disposed on a photo-receiving surface side of the first anti-reflection film; and
a second anti-reflection film disposed on a photo-receiving surface side of the intermediate film, wherein
at least one of the first anti-reflection film, the intermediate film, and the second anti-reflection film has different film thicknesses for respective colored lights to be received.

2. The solid-state imaging device according to claim 1, wherein
at least one of the first anti-reflection film, the intermediate film, and the second anti-reflection film is formed to have a thicker film thickness in a region in proportion as the region receives the colored light with a longer wavelength.

3. The solid-state imaging device according to claim 1, wherein
the photoelectric conversion element is disposed corresponding to each of at least red light, green light, and blue light, and
at least one of the first anti-reflection film, the intermediate film, and the second anti-reflection film is formed to have a region for receiving red light, a region for receiving green light, and a region for receiving blue light, the region for receiving red light being thicker than the region for receiving green light, the region for receiving green light being thicker than the region for receiving blue light.

4. The solid-state imaging device according to claim 1, wherein
the second anti-reflection film is a silicon nitride film.

5. The solid-state imaging device according to claim 1, wherein
the intermediate film is a silicon oxide film.

6. A solid-state imaging device, comprising:
a photoelectric conversion element disposed corresponding to each of a plurality of colored lights;
a first anti-reflection film disposed on a photo-receiving surface side of the photoelectric conversion element;
an intermediate film disposed on a photo-receiving surface side of the first anti-reflection film; and
a second anti-reflection film disposed on a photo-receiving surface side of the intermediate film, wherein
the second anti-reflection film is disposed in a region except a region for receiving a predetermined colored light among the plurality of colored lights.

7. The solid-state imaging device according to claim 6, wherein
the second anti-reflection film is disposed in a region except a region for receiving a colored light with a shortest wavelength among the plurality of colored lights.

8. The solid-state imaging device according to claim 6, wherein
the photoelectric conversion element is disposed corresponding to each of at least red light, green light, and blue light, and
the second anti-reflection film is disposed in a region except at least a region for receiving the blue light.

9. The solid-state imaging device according to claim 6, wherein
the photoelectric conversion element is disposed corresponding to each of at least red light, green light, and blue light, and
the second anti-reflection film is disposed in a region except at least a region for receiving the red light.

10. The solid-state imaging device according to claim 6, wherein
the photoelectric conversion element is disposed corresponding to each of at least red light, green light, and blue light, and
the second anti-reflection film is disposed in a region except at least a region for receiving the green light.

11. The solid-state imaging device according to claim 6, wherein
the second anti-reflection film is a silicon nitride film.

12. The solid-state imaging device according to claim 6, wherein
the intermediate film is a silicon oxide film.

13. A method for manufacturing a solid-state imaging device, comprising:
forming a photoelectric conversion element corresponding to each of a plurality of colored lights;
forming a first anti-reflection film on a photo-receiving surface side of the photoelectric conversion element;
forming an intermediate film on a photo-receiving surface side of the first anti-reflection film;
forming a second anti-reflection film on a photo-receiving surface side of the intermediate film; and
forming at least one of the first anti-reflection film, the intermediate film, and the second anti-reflection film having different film thicknesses for respective colored lights to be received.

14. The method for manufacturing the solid-state imaging device according to claim 13, further comprising
forming at least one of the first anti-reflection film, the intermediate film, and the second anti-reflection film having a thicker film thickness in a region in proportion as the region receives the colored light with a longer wavelength.

15. The method for manufacturing the solid-state imaging device according to claim 13, further comprising:
forming the photoelectric conversion element corresponding to each of at least red light, green light, and blue light; and
forming at least one of the first anti-reflection film, the intermediate film, and the second anti-reflection film having a region for receiving green light, a region for receiving red light, and a region for receiving blue light, the region for receiving green light being thinner than the region for receiving red light, the region for receiving blue light being thinner than the region for receiving green light.

16. The method for manufacturing the solid-state imaging device according to claim 13, further comprising
forming the second anti-reflection film of a silicon nitride film.

17. The method for manufacturing the solid-state imaging device according to claim 13, further comprising
forming the intermediate film of a silicon oxide film.
